(19) United States
(12) Patent Application Publication
(10) Pub. No.: US 2005/0208393 A1
(43) Pub. Date: Sep. 22, 2005

(54) Photomask and method for creating a protective layer on the same

(76) Inventors: Laurent Dieu, Austin, TX (US); Christian Chovino, Austin, TX (US)

Correspondence Address: BAKER BOTTS L.L.P.;PATENT DEPARTMENT, 98 SAN JACINTO BLVD., SUITE 1500, AUSTIN, TX, 78701-4039, US

(21) Appl. No.: 11/134,204

(22) Filed: May 20, 2005

Related U.S. Application Data
(63) Continuation of application No. PCT/US03/37477, filed on Nov. 25, 2003.
(60) Provisional application No. 60/428,999, filed on Nov. 25, 2002.
(60) Provisional application No. 60/457,400, filed on Mar. 25, 2003.

(51) Int. Cl. G03F 9/00; G03C 5/00

(52) U.S. Cl. 430/5; 430/322; 430/324

(57) ABSTRACT

A photomask and method for creating a protective layer on the photomask are disclosed. The method includes placing a photomask including a patterned layer formed on at least a portion of a substrate in a chamber. Oxygen is introduced into the chamber proximate the patterned layer and the photomask is exposed to radiant energy that initiates a reaction between the oxygen and the patterned layer in order to passivate the patterned layer and prevent optical properties of the patterned layer from being altered by a cleaning process.

### RELATED APPLICATIONS

This application is a continuation of PCT application PCT/US2003/37477 entitled “Photomask and Method for Creating a Protective Layer on the Same,” filed by Laurent Dieu et al. on Nov. 25, 2003, which claims the benefit of U.S. Provisional Application Ser. No. 60/428,999 entitled “Photomask and Method for Creating a Protective Layer on the Same,” filed by Laurent Dieu et al. on Nov. 25, 2002 and U.S. Provisional Application Ser. No. 60/457,400 entitled “Photomask and Method for Creating a Protective Layer on the Same,” filed by Laurent Dieu et al. on Mar. 25, 2003.

### TECHNICAL FIELD OF THE INVENTION

The present invention relates in general to photolithography and, more particularly to a photomask and method for creating a protective layer on the same.

### BACKGROUND OF THE INVENTION

As semiconductor manufacturers continue to produce smaller devices, the requirements for photomasks used in the fabrication of these devices continue to tighten. Photomasks, also known as reticles or masks, typically include a substrate having a non-transmissive or partially transmissive layer formed on one surface of the substrate. The non-transmissive or partially transmissive layer typically includes a pattern representing an image that may be transferred onto a semiconductor wafer in a lithography system. As feature sizes of the semiconductor devices decrease, the corresponding images on the photomask also become smaller and more complex. Consequently, the quality of photomasks has become one of the most crucial elements in establishing a robust and reliable semiconductor fabrication process.

Characteristics of a photomask that define quality include the flatness of an associated substrate, uniform dimensions of features formed by an associated non-transmissive or partially transmissive layer and transmission properties of the substrate and the non-transmissive or partially transmissive layer. These characteristics may be altered by various processes during the manufacture of a photomask, which may reduce the quality of the photomask. For example, a photomask typically may be cleaned at least one time during the manufacturing process to remove any contaminants that may be present on the exposed surfaces. Each cleaning process may alter transmission properties of the substrate, partially transmissive layer and/or non-transmissive layer. If the transmission properties are altered, a pattern formed on the photomask may not be accurately transferred from the photomask to a semiconductor wafer, thus causing defects or errors in microelectronic devices formed on the wafer.

One technique for reducing potentially harmful effects of a cleaning process on the transmission properties of a photomask may be to alter the cleaning process. For example, a conventional cleaning process may involve dipping a photomask in an alkali solution, e.g., ammonia/hydrogen peroxide. This type of solution, however, may cause a drastic change in transmittance and/or phase angle of certain materials used to form a partially transmissive layer (e.g., MoSiON used on embedded phase shift photomasks) because the cleaning solution may react with the partially transmissive material, which may cause physical changes. The physical changes may include increasing surface roughness of the partially transmissive material and/or reducing thickness of the material. Photomasks including a partially transmissive layer, therefore, are typically cleaned with pure water to avoid changes in the transmission properties that may be caused by alkali solutions. Cleaning with pure water, however, does not typically remove all contaminants from the surface of a photomask, which may reduce the quality of an image projected onto a semiconductor wafer.

### SUMMARY OF THE INVENTION

In accordance with teachings of the present invention, disadvantages and problems associated with cleaning a photomask have been substantially reduced or eliminated. In a particular embodiment, a method for creating a protective layer on a photomask includes exposing a photomask to radiant energy that initiate a reaction between the oxygen and a patterned layer in order to passivate the patterned layer and prevent optical properties of the patterned layer from being altered by a cleaning process.

In accordance with another embodiment of the present invention, a method for creating a protective layer on a photomask includes placing a photomask including a patterned layer formed on at least a portion of a substrate in a chamber. Oxygen is introduced into the chamber proximate the photomask. The photomask is exposed to radiant energy that causes the oxygen to react with the patterned layer to passivate an exposed surface of the patterned layer. The photomask is exposed to radiant energy that initiates a reaction between the oxygen and the patterned layer in order to passivate the patterned layer and prevent optical properties of the patterned layer from being altered by a cleaning process.

In accordance with another embodiment of the present invention, a photomask includes a patterned layer formed on at least a portion of a substrate. A protective layer is formed on the patterned layer by exposing the patterned layer to radiant energy and oxygen. The protective layer prevents optical properties of the patterned layer from being altered by a cleaning process.

In accordance with a further embodiment of the present invention, a photomask blank includes a partially transmissive layer formed on at least a portion of a substrate. A protective layer is formed on at least a portion of the patterned layer by passivating an exposed surface of the partially transmissive layer. The protective layer prevents optical properties of the partially transmissive layer from being altered by a cleaning process. A resist layer is formed on at least a portion of the protective layer.

Important technical advantages of certain embodiments of the present invention include a passivation process that forms a protective layer on exposed surfaces of a partially transmissive layer on a photomask. Before the photomask is subjected to a cleaning process, the partially transmissive layer may be exposed to oxygen and radiant energy such that the oxygen reacts with the partially transmissive layer. The reaction preferably passivates the exposed surface of the partially transmissive layer and makes the partially transmissive layer more resistant to changes that may be caused by an aggressive clean.

Another important technical advantage of certain embodiments of the present invention includes a passivation process that minimizes the effects of aggressive cleaning processes on a partially transmissive layer of a photomask. After the passivation process, a protective layer may be formed on the partially transmissive layer. The protective layer prevents aggressive clean techniques from substantially changing the surface roughness or thickness of the partially transmissive layer. Furthermore, optical properties of the partially transmissive layer are not substantially altered because the cleaning process may only remove a very small amount of material from the partially transmissive layer.

All, some, or none of these technical advantages may be present in various embodiments of the present invention. Other technical advantages will be readily apparent to one skilled in the art from the following figures, descriptions, and claims.

### BRIEF DESCRIPTION OF THE DRAWINGS

A more complete and thorough understanding of the present embodiments and advantages thereof may be acquired by referring to the following description taken in conjunction with the accompanying drawings, in which like reference numbers indicate like features, and wherein:

FIG. 1 illustrates a cross-sectional view of a photomask assembly that includes a protective layer according to the teachings of the present invention;

FIG. 2 illustrates a cross-sectional view of a photomask blank that includes a protective layer according to the teachings of the present invention;

FIGS. 3A and 3B respectively illustrate graphs of transmittance and phase of an absorber layer on a photomask after the photomask is subjected to multiple cleaning processes according to teachings of the present invention;

FIGS. 4A and 4B respectively illustrate graphs of transmittance and phase of an layer of SiN—TiN on a photomask after the photomask is subjected to multiple cleaning processes according to teachings of the present invention;

FIGS. 5A and 5B respectively illustrate graphs of transmittance and phase of an layer of MoSiON on a photomask after the photomask is subjected to multiple cleaning processes according to teachings of the present invention; and

FIG. 6 illustrates a flow chart of a method for forming a protective layer on a photomask according to teachings of the present invention.

### DETAILED DESCRIPTION OF THE INVENTION

Preferred embodiments of the present invention and their advantages are best understood by reference to FIGS. 1 through 6, where like numbers are used to indicate like and corresponding parts.

FIG. 1 illustrates a cross-sectional view of photomask assembly 10 that may be inspected by automatically transferring a defect image from an inspection system to a database. Photomask assembly 10 includes photomask 12 coupled to pellicle assembly 14. Substrate 16 and patterned layer 18 cooperate with each other to form portions of photomask 12. Photomask 12 may also be described as a mask or reticle and may have a variety of sizes and shapes, including but not limited to round, circular, rectangular, or square. Photomask 12 may also be any variety of photomask types, including, but not limited to, a one-time master, a five-inch reticle, a six-inch reticle, a nine-inch reticle or any other appropriately sized reticle that may be used to project an image of a circuit pattern onto a semiconductor wafer. Photomask 12 may further be a binary mask, a phase shift mask (PSM), an optical proximity correction (OPC) mask or any other type of mask suitable for use in a lithography system.

Photomask 12 includes patterned layer 18 formed on substrate 16 that, when exposed to electromagnetic energy in a lithography system, projects a pattern onto a surface of a semiconductor wafer (not expressly shown). Substrate 16 may be a transparent material such as quartz, synthetic quartz, fused silica, magnesium fluoride (MgF₂), calcium fluoride (CaF₂), or any other suitable material that transmits at least seventy-five percent (75%) of incident light having a wavelength between approximately 10 nanometers (nm) and approximately 450 nm. In an alternative embodiment, substrate 16 may be a reflective material such as silicon or any other suitable material that reflects greater than approximately fifty percent (50%) of incident light having a wavelength between approximately 10 nm and 450 nm.

Patterned layer 18 may be a metal material such as chrome, chromium nitride, a metallic oxy-carbo-nitride (e.g., MOCN, where the M is selected from the group consisting of chromium, cobalt, iron, zinc, molybdenum, niobium, tantalum, titanium, tungsten, aluminum, magnesium and silicon), or any other suitable material that absorbs electromagnetic energy with wavelengths in the ultraviolet (UV) range, deep ultraviolet (DUV) range, vacuum ultraviolet (VUV) range and extreme ultraviolet range (EUV). In an alternative embodiment, patterned layer 18 may be a partially transmissive material, such as molybdenum silicide (MoSi), which has a transmissivity of approximately one percent (1%) to approximately thirty percent (30%) in the UV, DUV, VUV and EUV ranges.

Frame 20 and pellicle film 22 may form pellicle assembly 14. Frame 20 is typically formed of anodized aluminum, although it may alternatively be formed of stainless steel, plastic or other suitable materials that do not degrade or outgas when exposed to electromagnetic energy within a lithography system. Pellicle film 22 may be a thin film membrane formed of a material such as nitrocellulose, cellulose acetate, an amorphous fluoropolymer, such as TEFLON® AF manufactured by E. I. du Pont de Nemours and Company or CYTOP® manufactured by Asahi Glass, or another suitable film that is transparent to wavelengths in the UV, DUV, EUV and/or VUV ranges. Pellicle film 22 may be prepared by conventional techniques such as spin casting.

Pellicle film 22 protects photomask 12 from contaminants, such as dust particles, by ensuring that the contaminants remain a defined distance away from photomask 12. This may be especially important in a lithography system. During a lithography process, photomask assembly 10 is exposed to electromagnetic energy produced by a radiant energy source within the lithography system. The electromagnetic energy may include light of various wavelengths, such as wavelengths approximately between the I-line and G-line of a Mercury arc lamp, or DUV, VUV or EUV light. Pellicle film 22 is preferably designed to allow a large percentage of the electromagnetic energy to pass therethrough. Contaminants collected on pellicle film 22 will likely be out of focus at the surface of a wafer being processed and, therefore, an exposed image on the wafer will generally be clear of any defects associated with pellicle film 22. Pellicle film 22 and photomask 12 may be satisfactorily used with all types of electromagnetic energy and are not limited to lightwaves described in this application.

Photomask 12 may be formed from a photomask blank using a standard lithography process. In a lithography process, a mask pattern file that includes data for patterned layer 18 may be generated from a mask layout file. The mask layout file may include polygons that represent transistors and electrical connections for an integrated circuit. The polygons in the mask layout file may further represent different layers of the integrated circuit when fabricated on a semiconductor wafer. For example, a transistor may be formed on a semiconductor wafer with a diffusion layer and a polysilicon layer. The mask layout file may include one or more polygons drawn on the diffusion layer and one or more polygons drawn on the polysilicon layer. The polygons for each layer may be converted into a mask pattern file that represents one layer of the integrated circuit. Each mask pattern file may be used to generate a photomask for the specific layer.

The desired pattern may be imaged into a resist layer of the photomask blank using a laser, electron beam, or X-ray lithography system. In one embodiment, a laser lithography system uses an Argon-Ion laser that emits light having a wavelength of approximately 364 nanometers (nm). In alternative embodiments, the laser lithography system may use lasers emitting light at wavelengths from approximately 150 nm to approximately 300 nm. Photomask 12 may be fabricated by developing and etching exposed areas of the resist layer to create a pattern, etching portions of patterned layer 18 not covered by resist, and removing any undeveloped resist to create patterned layer 18 over substrate 16.

Photomask 12 may be a phase shift mask (PSM), including, but not limited to, an alternating PSM, an attenuated PSM, and a multitone PSM. In one embodiment, photomask 12 may be formed from an embedded attenuated phase shift mask (EAPSM) blank (not expressly shown). For some applications the photomask blank may be generally described as an EAPSM blank with a partially transmissive layer and a non-transmissive layer formed on at least a portion of the partially transmissive layer. An EAPSM generally allows smaller features to be manufactured on a semiconductor wafer because specific portions of the pattern on the photomask are phase shifted to provide sharper feature edges.

Patterned layer 18 of photomask 12 may be formed of homogeneous, graded or multilayered materials as long as photomask 12 satisfies optical properties of a semitransparent medium providing desired transmission and phase shift characteristics. In one embodiment, patterned layer 18 may be formed of a material having a formula of Mₓ[Si]₍₁₋ₓ₎O_{y}N_{(1-y)}, where M is a metal selected from Groups IV, V and VI, x varies from 0 to 1 and y varies from 0 to 1-x. In another embodiment, patterned layer 18 may be formed of a multi-layer material, such as SiN—TiN. In other embodiments, patterned layer 18 may be formed of any suitable material that may be partially transmissive to wavelengths in the UV, DUV, EUV or VUV ranges. The resulting structure, when used in a lithography system, may be capable of producing a phase shift of approximately 180 degrees at selected exposure wavelengths of less than approximately 400 nanometers.

A conventional cleaning process, such as an aggressive clean, may be used to remove contaminants from photomask 12 including a partially transmissive material by passivating patterned layer 18 to form protective layer 24. In one embodiment, patterned layer 18 may be passivated by exposing patterned layer 18 to radiant energy in the presence of an oxygen rich environment. The radiant energy functions to initiate a reaction between the oxygen and exposed surfaces of patterned layer 18. In one embodiment, the radiant energy may have a wavelength below approximately 300 nanometers. The passivation process may be performed at any time during a photomask manufacturing process when at least a portion of patterned layer 18 is exposed. The passivation process may further be used on a photomask including multiple layers of partially transmissive material or any other material that may be damaged by an aggressive clean without the use of the protective coating. After the UV-oxygen treatment, patterned layer 18 may include protective layer 24 such that the cleaning process does not effect the surface characteristics, thickness and/or optical properties of patterned layer 18.

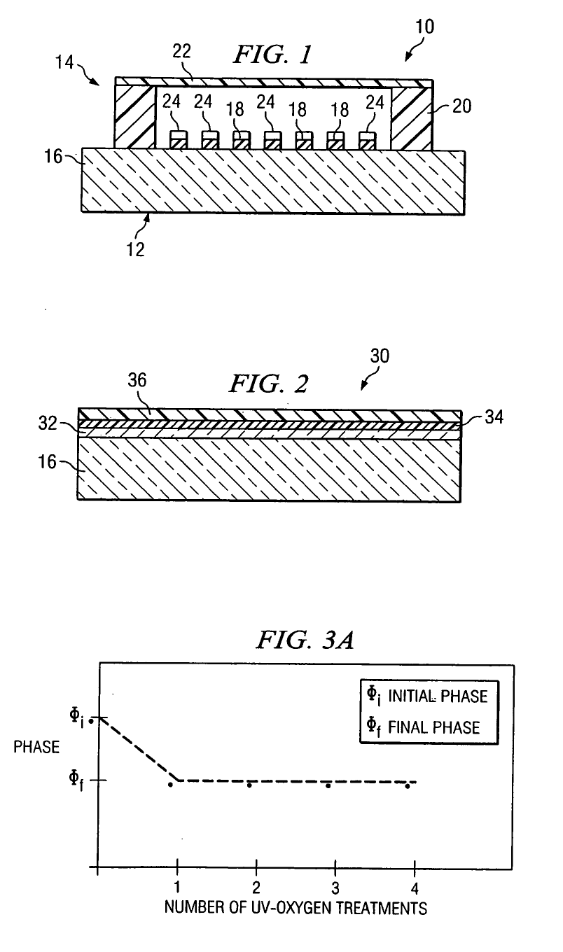

FIG. 2 illustrates a cross-sectional view of photomask blank 30 including a protective layer formed on a partially transmissive layer. Photomask blank 30 may include substrate 16, partially transmissive layer 32, protective layer 34 and resist layer 36. In one embodiment, partially transmissive layer 32 may be formed of homogeneous or graded layer of Mₓ[Si]₍₁₋ₓ₎O_{y}N_{(1-y)}, where M is a metal selected from Groups IV, V and VI, x varies from 0 to 1 and y varies from 0 to 1-x. In another embodiment, partially transmissive layer 32 may be formed of a multi-layer material, such as SiN—TiN. During a photomask manufacturing process, a pattern may be formed in partially transmissive layer 32 to create a patterned layer (e.g., patterned layer 18 as illustrated in FIG. 1). Resist layer 36 may be any positive or negative resist. Although not specifically shown, photomask blank 30 may additionally include a non-transmissive layer (e.g., chrome) located between protective layer 34 and resist layer 36.

Protective layer 34 may be formed by passivating exposed surfaces of partially transmissive layer 32 such that a cleaning solution used in a cleaning process does not react with partially transmissive layer 32 and alter optical properties associated with partially transmissive layer 32. In one embodiment, protective layer 34 may be formed during deposition of partially transmissive layer 32 by significantly increasing the concentration of oxygen or ozone in the deposition chamber near the end of the deposition process (e.g., during the final five to ten seconds of the deposition process). Protective layer 34 may be formed when the oxygen reacts with the partially transmissive material being deposited.

In another embodiment, protective layer 34 may be formed during an anneal step that occurs after partially transmissive layer 32 has been deposited. During the anneal, oxygen or ozone may be introduced near the surface of partially transmissive layer 32. The thermal energy from the anneal may cause exposed surfaces of partially transmissive layer 32 to react with the oxygen or ozone to form protective layer 34.

In a further embodiment, protective layer 34 may be formed by introducing oxygen or ozone near the surface of partially transmissive layer 32 and exposing partially transmissive layer 32 to radiant energy. The radiant energy may initiate a reaction between the oxygen and partially transmissive layer 32. This reaction may passivate exposed surfaces of partially transmissive layer 32 to form protective layer 34. In one embodiment, the oxygen or ozone may react with partially transmissive layer such that protective layer 34 is formed of silicon dioxide (SiO₂). The exact thickness of protective layer 32 may depend on the optical properties desired and/or the duration of the passivation process.

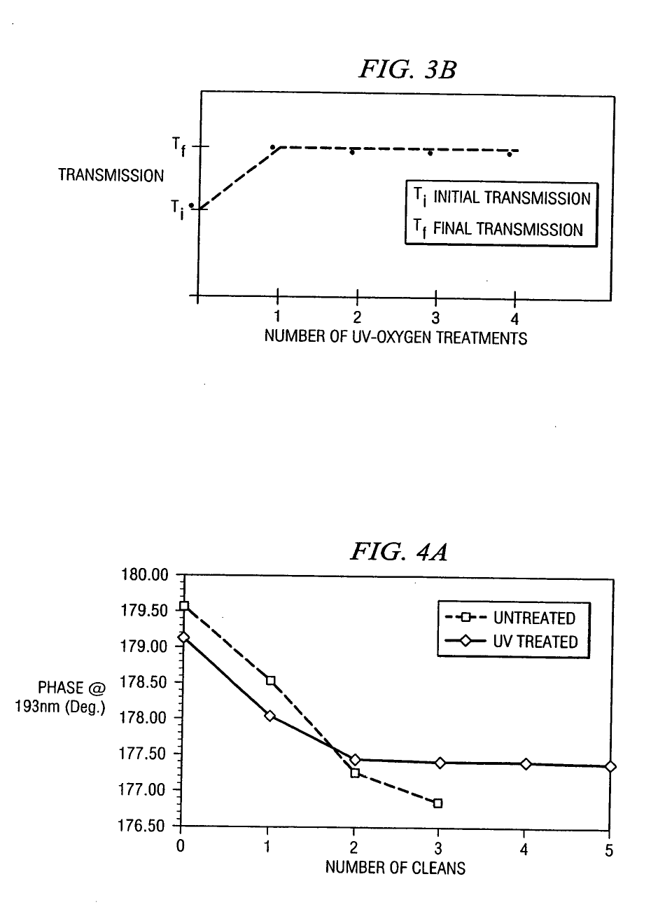

FIGS. 3A and 3B respectively illustrate graphs of the change in phase angle and transmission of patterned layer 18 when patterned layer 18 on photomask 12 is exposed to radiant energy and oxygen. As shown in FIG. 2A, patterned layer 18 may have an initial phase angle. In one embodiment, the initial phase angle may be determined by a relationship between the thickness of patterned layer 18 and the exposure wavelength of a lithography system. When photomask 12 is exposed to radiant energy in an oxygen rich environment, the radiant energy may cause a reaction to occur between the oxygen and patterned layer 18. This reaction may passivate patterned layer 18 by creating protective layer 24 on the surface of patterned layer 18. Protective layer 24 functions to protect patterned layer 18 such that patterned layer 18 may be more resistant to an aggressive clean, such as a cleaning solution including sulfuric acid and/or peroxide. As illustrated by FIG. 2A, the UV-oxygen treatment process may decrease the phase angle of patterned layer 18. In one embodiment, the phase angle may decrease by approximately one degree. For any subsequent UV-oxygen treatments, the phase angle may remain substantially constant.

As shown in FIG. 3B, patterned layer 18 may transmit an initial percentage of radiant energy. In one embodiment, the initial transmission percentage may be determined by a relationship between the thickness of patterned layer 18 and the exposure wavelength of a lithography system. When photomask 12 is initially subjected to the UV-oxygen treatment, the initial percentage of radiant energy transmitted by patterned layer 18 may increase. In one embodiment, the initial percentage may increase by approximately 0.06 percent. Again, for subsequent UV-oxygen treatment processes, the transmittance may remain substantially constant.

As illustrated in FIGS. 3A and 3B, the passivation process may alter optical properties of patterned layer 18. In order to obtain the desired final phase and transmission values, the chemistry and/or thickness of patterned layer 18 may be adjusted to compensate for the changes that occur due to the exposure to radiant energy and oxygen. For example, the phase angle of a partially transmissive material may be defined by the following formula:

$$ϕ = \frac{2 π}{λ} ( n - 1 ) d$$

where λ is the exposure wavelength of a lithography system, n is the index of refraction of a partially transmissive layer and d is the thickness of the partially transmissive material. Therefore, in order to compensate for the decrease in phase angle caused by the UV-oxygen treatment, patterned layer 18 formed of a partially transmissive material may have a slightly larger index of refraction and/or patterned layer 18 may be slightly thicker.

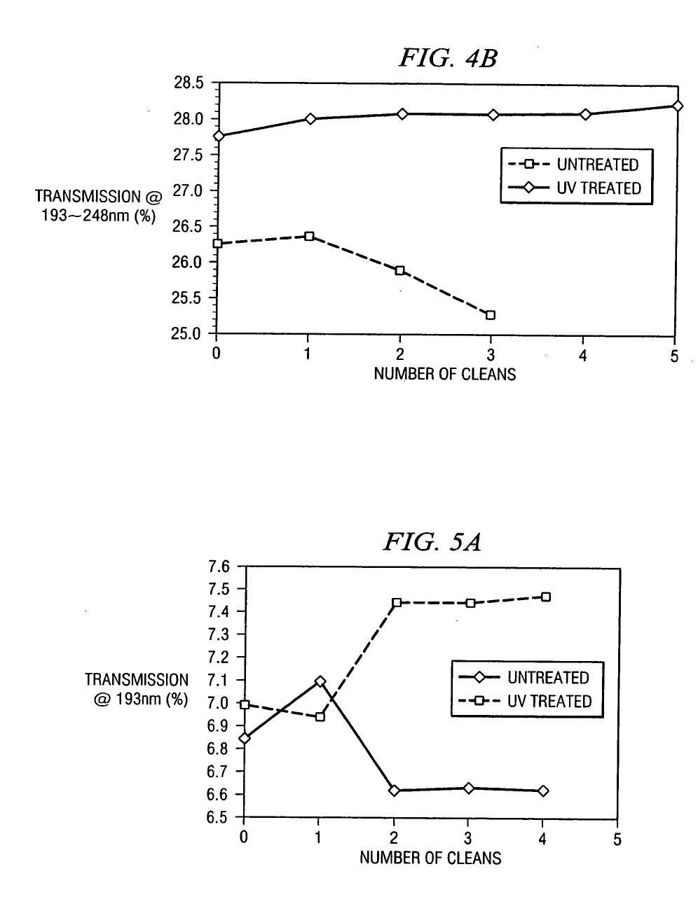

FIGS. 4A and 4B respectively illustrate graphs of the change in phase angle and transmission of an untreated patterned layer and a UV treated patterned layer formed of SiN—TiN. In the illustrated embodiment, the phase angle and transmission were measured at a wavelength of approximately 248 nm and the phase angle was converted to corresponding values at a wavelength of approximately 193 nm.

As shown in FIG. 4A, patterned layer 18 may be formed of SiN—TiN and may have an initial phase angle of approximately 179 degrees. If patterned layer 18 is untreated (e.g., no UV-oxygen treatment is applied before the first cleaning process), each cleaning process may alter the phase angle of patterned layer 18. In the illustrated embodiment, each cleaning process may reduce the phase angle of the untreated patterned layer by approximately one degree. If a UV-oxygen treatment is applied before an initial cleaning process, the UV-oxygen treatment may slightly decrease the phase angle of patterned layer 18. Protective layer 24 formed on patterned layer 18 during the UV-oxygen treatment, however, may prevent the initial cleaning process from altering the phase angle.

In the illustrated embodiment, a UV-oxygen treatment may be applied before the first cleaning process. The UV-oxygen treatment may decrease the phase angle by approximately one degree (1°). As further illustrated, if a second UV-oxygen treatment is applied, the phase angle may decrease slightly but protective layer 24 may prevent the cleaning process from causing any changes in the phase angle. Any further UV-oxygen treatments may not have an effect such that the phase angle of patterned layer 18 remains substantially constant during subsequent cleaning processes. In one embodiment, the UV-oxygen treatment may be applied for approximately twenty minutes using a wavelength of approximately 172 nm. In other embodiments, the amount of time for applying the UV-oxygen treatment may vary depending on the influence of the radiant energy and the oxygen concentration near the surface of patterned layer 18.

As shown in FIG. 4B, an untreated patterned layer may have an initial transmittance of approximately 26 percent and patterned layer 18 including protective layer 24 may have an initial transmittance of approximately 28 percent. If patterned layer 18 remains untreated, each cleaning process may vary the transmittance such that the transmittance decreases after each clean. However, when a UV-oxygen treatment is applied to patterned layer 18 before an initial cleaning process, the UV-oxygen treatment may slightly increase the transmittance of patterned layer 18. Protective layer 24 formed on patterned layer 18 by the UV-oxygen treatment, however, may prevent the initial cleaning process from causing any changes in the transmittance.

In the illustrated embodiment, the first UV-oxygen treatment may increase the transmittance of patterned layer 18 by less than approximately 0.2 percent. As further illustrated, if a second UV-oxygen treatment is applied, the transmittance may increase slightly but protective layer 24 again may prevent the cleaning process from altering the transmittance. Any further UV-oxygen treatments applied to patterned layer 18 may not change the transmittance. Additionally, protective layer 24 prevents subsequent cleaning processes from changing the properties of patterned layer 18 and the transmittance of patterned layer 18 may remain substantially constant.

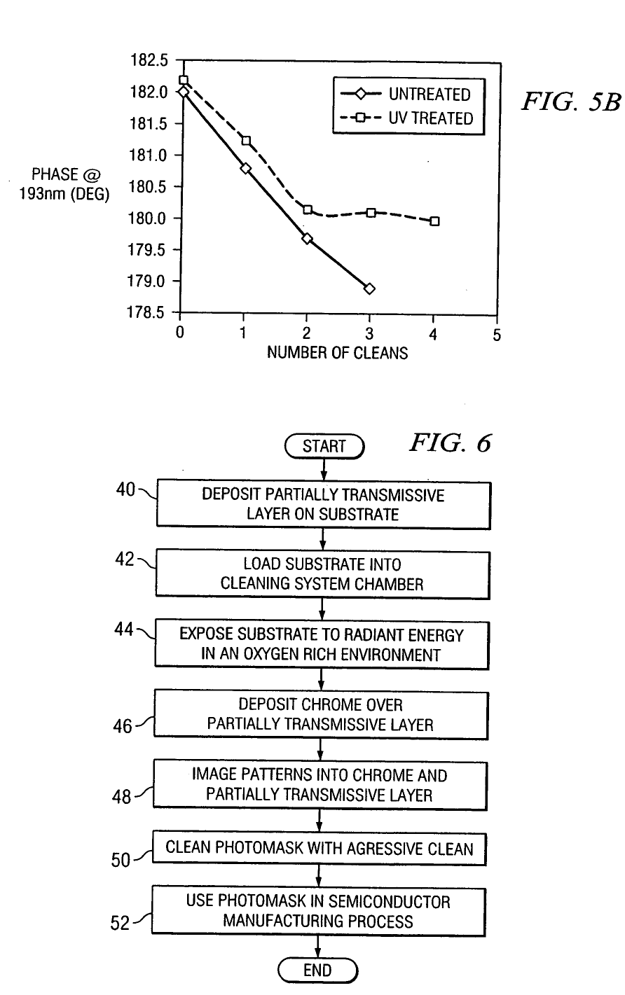

FIGS. 5A and 5B respectively illustrate graphs of the change in phase angle and transmission of an untreated patterned layer and a UV treated patterned layer formed of MoSiON. In the illustrated embodiment, the phase and transmission were measured at a wavelength of approximately 248 nm and converted to the corresponding values at a wavelength of approximately 193 nm.

As shown in FIG. 5A, an unpassivated patterned layer may have an initial transmittance of approximately 6.8 percent and passivated patterned layer 18 including protective layer 24 may have an initial transmittance of approximately seven percent (7%). If patterned layer 18 is untreated (e.g., no UV-oxygen treatment is applied before the first cleaning process), each cleaning process may alter the transmittance of patterned layer 18. If a UV-oxygen treatment is applied before an initial cleaning process, the UV-oxygen treatment may slightly increase the transmittance of patterned layer 18. Protective layer 24 formed on patterned layer 18 during the UV-oxygen treatment, however, may prevent the initial cleaning process from altering the transmittance.

In the illustrated embodiment, UV-oxygen treatments may be applied before the first and second cleaning process. The two UV-oxygen treatments may increase the transmittance by approximately 0.6 percent. As further illustrated, if further UV-oxygen treatments are applied, the transmittance of patterned layer may remain substantially constant and protective layer 24 may prevent the cleaning processes from causing any changes in the transmittance of patterned layer 18. In one embodiment, the UV-oxygen treatment may be applied for approximately thirty minutes using a wavelength of approximately 172 nm. In other embodiments, the total of time for the UV-oxygen treatment may vary depending on the influence of the radiant energy and/or the oxygen concentration near the surface of patterned layer 18.

As shown in FIG. 5B, patterned layer 18 formed of MoSiON may have an initial phase angle of approximately 182 degrees. If patterned layer 18 remains untreated, each cleaning process may vary the phase angle such that the phase angle decreases after each clean. However, when a UV-oxygen treatment is applied to patterned layer 18 before an initial cleaning process, the UV-oxygen treatment may slightly decrease the phase angle of patterned layer 18. Protective layer 24 formed on patterned layer 18 by the UV-oxygen-treatment, however, may prevent the initial cleaning process from causing any changes in the phase angle.

In the illustrated embodiment, the first UV-oxygen treatment may decrease the phase angle of patterned layer 18 by approximately one degree (1°). As further illustrated, if a second UV-oxygen treatment is applied, the phase angle may decrease slightly but protective layer 24 again may prevent the cleaning process from altering the phase angle. Any further UV-oxygen treatments applied to patterned layer 18 may not change the phase angle. Additionally, protective layer 24 prevents the cleaning process from changing the properties of patterned layer 18 and the phase angle of patterned layer 18 may remain substantially constant.

FIG. 6 illustrates a flow chart for a method for creating a protective coating on a photomask blank used to manufacture an EAPSM. Generally, a partially transmissive layer may be deposited on a substrate. The partially transmissive material may be exposed to radiant energy in the presence of oxygen to passivate the partially transmissive layer and make the partially transmissive layer more resistant to aggressive cleaning processes.

At step 40, a partially transmissive layer may be deposited on a substrate (e.g., substrate 16 as illustrated in FIGS. 1 and 2). In one embodiment, the partially transmissive layer may be a homogeneous or graded layer formed of Mₓ[Si]₍₁₋ₓ₎O_{y}N_{(1-y)}, where M may be a metal selected from Groups IV, V and VI, x varies between 0 and 1 and y varies between 0 and (1-x). In another embodiment, the partially transmissive layer may be a multilayer material of SiN—TiN. The thickness and exact chemistry of the partially transmissive layer may be determined based on how exposure to radiant energy and oxygen affects the optical properties (e.g., phase angle and transmittance) of the material.

Once the partially transmissive layer has been deposited on the substrate and prior to subjecting the photomask to a cleaning process, the substrate may be placed in a chamber at step 42. Oxygen or ozone may be introduced near the surface of the partially transmissive layer and radiant energy having a wavelength below approximately 300 nanometers may be directed at the surface of the partially transmissive layer in order to passivate the surface of the partially transmissive layer at step 44. In operation, steps 42 and 44 may alternatively occur after step 48.

The radiant energy may initiate a reaction between the oxygen and the partially transmissive layer, which passivates the partially transmissive layer and forms a protective layer. In one embodiment, the protective layer may be formed of silicon dioxide (SiO₂). The passivation process makes the partially transmissive layer resistant to a cleaning process such that the cleaning process does not substantially change physical and optical properties of the partially transmissive layer. In one embodiment, the passivation process may be applied to the substrate prior to each cleaning process. In another embodiment, the passivation process may be applied before an initial cleaning process.

The amount of time that the UV-oxygen treatment may be applied to the partially transmissive layer may vary depending on the influence of the UV radiation and/or the oxygen concentration. The oxygen concentration in the chamber may be varied during the treatment process to provide the desired flow over the partially transmissive layer. In one embodiment, the oxygen content may be below or above an atmospheric concentration of approximately twenty percent. In another embodiment, the amount of radiant energy directed at the partially transmissive layer and the oxygen concentration near the surface of the partially transmissive layer may be tuned to create the appropriate protective layer in a time period of between approximately two seconds and approximately thirty minutes.

At step 46, a non-transmissive layer, such as chrome, may be deposited over the partially transmissive layer. An EAPSM may then be formed by imaging patterns into the partially transmissive and non-transmissive layers at step 48. After the patterns have been formed, the photomask may be cleaned at step 50. The cleaning process may remove contaminants from exposed surfaces of the substrate, partially transmissive layer and non-transmissive layer. During the cleaning process, the phase angle of the partially transmissive layer may decrease slightly and the transmittance of the partially transmissive layer may increase slightly. In one embodiment, the phase may decrease by approximately one degree and the transmittance may increase be approximately 0.06 percent during an initial cleaning process and may remain stable for subsequent cleaning processes.

The EAPSM may be used to project an image onto a semiconductor wafer at step 52. After numerous uses in a semiconductor manufacturing process, contaminants may collect on the surface of the photomask. In order to preserve the quality of the photomask, a cleaning process may be used to remove the contaminants. By passivating the partially transmissive layer to form a protective layer, the optical properties of the partially transmissive layer may remain unchanged after the first cleaning process. Thus, the photomask may be properly cleaned without affecting the quality of the image projected.

Although the present invention has been described with respect to a specific preferred embodiment thereof, various changes and modifications may be suggested to one skilled in the art and it may be intended that the present invention encompass such changes and modifications fall within the scope of the appended claims.

1. A method for creating a protective layer on a photomask, comprising:
placing a photomask including a patterned layer formed on at least a portion of a substrate in a chamber;
introducing oxygen into the chamber proximate the patterned layer;
exposing the photomask to radiant energy, the radiant energy operable to initiate a reaction between the oxygen and the patterned layer in order to passivate the patterned layer and prevent optical properties of the patterned layer from being altered by a cleaning process.

2. The method of claim 1, wherein the patterned layer comprises MₓSi₍₁₋ₓ₎O_{y}N_{(1-y)}, where M is selected from the group consisting of Group IV, Group V and Group VI metals.

3. The method of claim 1, further comprising the radiant energy including a wavelength below approximately 300 nanometers.

4. The method of claim 1, further comprising the reaction between the radiant energy and the oxygen forming a protective layer on the patterned layer.

5. The method of claim 1, further comprising the cleaning process including an aggressive clean.

6. The method of claim 1, wherein the photomask comprises an embedded attenuated phase shift photomask.

7. The method of claim 1, further comprising the optical properties of the patterned layer including a phase angle and a transmittance.

8. The method of claim 7, wherein the phase angle decreases by less than approximately one degree after the photomask is exposed to radiant energy and oxygen.

9. The method of claim 7, wherein the transmittance increases by less than approximately 0.06 percent after the photomask is exposed to radiant energy and oxygen.

10. The method of claim 1, further comprising exposing the photomask to radiant energy for a duration between approximately two seconds to approximately thirty minutes.

11. A photomask, comprising:
a substrate;
a patterned layer formed on at least a portion of the substrate; and
a protective layer formed on the patterned layer by exposing the patterned layer to radiant energy and oxygen, the protective layer operable to prevent optical properties of the patterned layer from being altered by a cleaning process.

12. The photomask of claim 11, wherein the patterned layer comprises MₓSi₍₁₋ₓ₎O_{y}N_{(1-y)}, where M is selected from the group consisting of Group IV, Group V and Group VI metals.

13. The photomask of claim 11, wherein the patterned layer comprises at least one layer of SiN and at least one layer of TiN.

14. The photomask of claim 11, further comprising the radiant energy including a wavelength below approximately 300 nanometers.

15. The photomask of claim 11, further comprising the optical properties of the patterned layer including phase angle and transmittance.

16. The photomask of claim 15, wherein the phase angle decreases by less than approximately one degree after the photomask is exposed to radiant energy and oxygen.

17. The photomask of claim 15, wherein the transmittance increases by less than approximately 0.06 percent after the photomask is exposed to radiant energy and oxygen.

18. The photomask of claim 11, further comprising the patterned layer including a thickness tuned to have a transmittance greater than a desired transmittance and a phase angle less than a desired phase angle at an exposure wavelength.

19. The photomask of claim 11, wherein the protective layer comprises SiO₂.

20. A photomask blank, comprising:
a substrate;
a partially transmissive layer formed on at least a portion of a substrate;
a protective layer formed on at least a portion of the partially transmissive layer, the protective layer formed by passivating an exposed surface of the partially transmissive layer;
the protective layer operable to prevent optical properties of the partially transmissive layer from being altered by a cleaning process; and
a resist layer formed on at least a portion of the protective layer.

21. The photomask blank of claim 20, further comprising the protective layer formed by increasing oxygen concentration during deposition of the partially transmissive layer.

22. The photomask blank of claim 20, further comprising the protective layer formed by introducing oxygen during an anneal of the partially transmissive layer.

23. The photomask blank of claim 20, further comprising the protective layer formed by reacting oxygen with the partially transmissive layer in the presence of radiant energy.

24. The photomask blank of claim 20, further comprising the radiant energy including a wavelength below approximately 300 nanometers.

25. The photomask blank of claim 20, further comprising the optical properties of the partially transmissive layer including phase angle and transmittance.

26. The photomask blank of claim 25, wherein the phase angle decreases by less than approximately one degree after formation of the protective layer.

27. The photomask blank of claim 25, wherein the transmittance increases by less than approximately 0.06 percent after formation of the protective layer.

28. The photomask blank of claim 20, further comprising the partially transmissive layer including a thickness tuned to have a transmittance greater than a desired transmittance and a phase angle less than a desired phase angle at an exposure wavelength.
